(19) United States
(12) Patent Application Publication
(10) Pub. No.: US 2026/0142643 A1
(43) Pub. Date: May 21, 2026

(54) WAFER-LEVEL-PACKAGED SILICON-PIEZOELECTRIC RESONATOR

(71) Applicant: University of Florida Research Foundation, Incorporated, Gainesville, FL (US)

(72) Inventor: Roozbeh Tabrizian, Gainesville, FL (US)

(21) Appl. No.: 18/950,644

(22) Filed: Nov. 18, 2024

Related U.S. Application Data
(60) Provisional application No. 63/600,422, filed on Nov. 17, 2023.

(51) Int. Cl. H03H 9/17; H03H 3/02; H03H 9/02; H03H 9/15

(52) U.S. Cl. CPC H03H 9/173; H03H 3/02; H03H 9/02448; H03H 2003/027; H03H 2009/155

(57) ABSTRACT

A method for manufacturing a micro-electro-mechanical systems (MEMS) platform is provided. The method includes depositing a piezoelectric layer on a first device layer of a first cavity-embedded silicon-on-insulator (SOI) substrate, wherein the first device layer is N-type doped and comprises a first thickness, polarizing the piezoelectric layer according to a desired pattern, bonding a second device layer comprising a second thickness to the piezoelectric layer, wherein the second device layer is N-type doped, and defining a resonator lateral geometry by forming trenches through the second device layer, the piezoelectric layer, and the first device layer.

### CROSS-REFERENCE TO RELATED APPLICATIONS

The present application claims priority to U.S. Provisional Application Ser. No. 63/600,422, titled “WAFER-LEVEL-PACKAGED SILICON-PIEZOELECTRIC RESONATOR,” filed Nov. 17, 2023, the contents of which are incorporated herein by reference in their entirety.

### ACKNOWLEDGMENT OF GOVERNMENT SUPPORT

This invention was made with government support under Agreement No. HR0011-23-9-0018, awarded by US DEPT OF DEFENSE DARPA. The government has certain rights in the invention.

### TECHNICAL FIELD

The present application generally relates to the technical field of micro-electro-mechanical systems (MEMS) platforms that enable realization of resonators. In particular, the present application relates to wafer-level-packaged silicon-piezoelectric resonators.

### BACKGROUND

MEMS platforms conventionally use metal electrodes, which dissipate energy into heat and cause the MEMS platform to be lossy. There is a need to create a MEMS platform capable of reducing or eliminating energy loss due to the metal electrodes.

### BRIEF SUMMARY

Various embodiments described herein relate to methods for manufacturing a MEMS platform. In accordance with various embodiments of the present disclosure, a method for manufacturing a micro-electro-mechanical systems (MEMS) platform is provided. The method includes depositing a piezoelectric layer on a first device layer of a first cavity-embedded silicon-on-insulator (SOI) substrate, wherein the first device layer is N-type doped and comprises a first thickness; polarizing the piezoelectric layer according to a desired pattern; bonding a second device layer comprising a second thickness to the piezoelectric layer, wherein the second device layer is N-type doped; and defining a resonator lateral geometry by forming trenches through the second device layer, the piezoelectric layer, and the first device layer.

### BRIEF DESCRIPTION OF THE DRAWINGS

The accompanying drawings, which constitute a part of the description, illustrate embodiments of the present invention and, together with the description thereof, serve to explain the principles of the present invention.

FIG. 1 illustrates a schematic cross-sectional view of a cavity-embedded silicon-on-insulator (SOI) substrate, according to some embodiments of the present disclosure.

FIG. 2 illustrates a schematic cross-sectional view of a first tetraethyl orthosilicate (TEOS) layer formed on the first device layer, according to some embodiments of the present disclosure.

FIG. 3 illustrates a schematic cross-sectional view of a first patterned TEOS layer formed on the first device layer, according to some embodiments of the present disclosure.

FIG. 4 illustrates a schematic cross-sectional view of a first trench formed in the first device layer, according to some embodiments of the present disclosure.

FIG. 5 illustrates a schematic cross-sectional view of the aluminum-scandium-nitride (AlScN) piezoelectric layer formed on the first device layer, according to some embodiments of the present disclosure.

FIG. 6 illustrates a schematic cross-sectional view of an engineered AlScN piezoelectric layer formed on the first device layer, according to some embodiments of the present disclosure.

FIG. 7 illustrates a schematic cross-sectional view of a second device layer formed on the AlScN piezoelectric layer, according to some embodiments of the present disclosure.

FIG. 8 illustrates a schematic cross-sectional view of second trenches formed in the second device layer, according to some embodiments of the present disclosure.

FIG. 9 illustrates a schematic cross-sectional view of a second tetraethyl orthosilicate (TEOS) layer formed on the second device layer, according to some embodiments of the present disclosure.

FIG. 10 illustrates a schematic cross-sectional view of a second patterned TEOS layer formed on the second device layer, according to some embodiments of the present disclosure.

FIG. 11 illustrates a schematic cross-sectional view of a doped poly-silicon layer formed on the second patterned TEOS layer, according to some embodiments of the present disclosure.

FIG. 12 illustrates a schematic cross-sectional view of a structure 1300 including a patterned doped poly-silicon layer formed on the second patterned TEOS layer, according to some embodiments of the present disclosure.

FIG. 13 illustrates a schematic cross-sectional view of third trenches formed in the first device layer, the AlScN piezoelectric layer, and the second device layer, according to some embodiments of the present disclosure.

FIG. 14 illustrates a schematic cross-sectional view of a second substrate, according to some embodiments of the present disclosure.

FIG. 15 illustrates a schematic cross-sectional view of the second substrate bonded to the structure, according to some embodiments of the present disclosure.

FIG. 16 illustrates a schematic cross-sectional view of a grinded second substrate bonded to the structure, according to some embodiments of the present disclosure.

FIG. 17 illustrates a schematic cross-sectional view of contact pads formed on the grinded handle layer, according to some embodiments of the present disclosure.

FIG. 18 illustrates a schematic perspective view of a resonator model, according to some embodiments of the present disclosure.

FIG. 19 illustrates a simulation of the resonator model, according to some embodiments of the present disclosure.

FIG. 20 illustrates a simulated admittance response as a function of a frequency of the resonator model in two scenarios, according to some embodiments of the present disclosure.

FIG. 21 illustrates a simulated temperature response as a function of a frequency of the resonator model in two scenarios, according to some embodiments of the present disclosure.

FIG. 22 illustrates a schematic perspective view of a gyroscope model, according to some embodiments of the present disclosure.

FIG. 23 illustrates a simulation of the gyroscope model in mode 1, according to some embodiments of the present disclosure.

FIG. 24 illustrates a simulation of the gyroscope model in mode 2, according to some embodiments of the present disclosure.

FIG. 25 illustrates a simulated output signal response as a function of a frequency of the gyroscope model, according to some embodiments of the present disclosure.

FIG. 26 illustrates a schematic perspective view of an accelerometer model, according to some embodiments of the present disclosure.

FIG. 27 illustrates a simulation of the accelerometer model with an in-plane axel, according to some embodiments of the present disclosure.

FIG. 28 illustrates a simulation of the accelerometer model with an out-of-plane axel, according to some embodiments of the present disclosure.

FIG. 29 depicts example operations for use with embodiments of the present disclosure.

### DETAILED DESCRIPTION

In order to clarify the purpose, technical solution details, and advantages of the embodiments of the present disclosure, the embodiments of the present disclosure are clearly and completely described in the following with reference to the accompanying drawings in the embodiments of the present disclosure. Clearly, the described embodiments are merely exemplary embodiments of the present disclosure, therefore shall not be interpreted as limiting the present disclosure. All other embodiments obtained by those skilled in the art without creative efforts according to the embodiments of the present disclosure are within the scope of the present disclosure.

A greater understanding of the present disclosure and it many advantages may be had from the following description, accompanied by illustrations. The following descriptions show embodiments and variants of the devices in the present invention, and their applications and fabrication method. They are, of course, not to be considered as limiting the invention. Numerous changes and modifications is made with respect to the invention.

The terms used in the embodiments of the present disclosure are merely for the purpose of describing particular embodiments but not intended to limit the present disclosure. Unless otherwise noted in the context, the singular form expressions “a”, “an”, “the” and “said” used in the embodiments and appended claims of the present disclosure are also intended to represent plural form expressions thereof.

It should be understood that the term “and/or” used herein is merely an association relationship describing associated objects, indicating that there may be three relationships, for example, A and/or B may indicate that three cases, e.g., An existing individually, A and B existing simultaneously, B existing individually. In addition, the character “/” herein generally indicates that the related objects before and after the character form an “or” relationship.

It should be noted that, the expressions such as “upper”, “lower”, “left”, “right” and the like mentioned in embodiments of the present disclosure are described with reference to the placement status in the accompanying drawings and should not be construed as limiting embodiments of the present disclosure. In addition, it should also be understood that, in the context, while referring to an element being formed “above” or “below” another element, it is possible that the element is directly formed “above” or “below” the other element, it is also possible that the element is formed “above” or “below” the other element via an intermediate element.

Embodiments herein relate to a micro-electro-mechanical systems (MEMS) platform that enables realization of high performance, low-power, and small-size sensors, actuators, and resonators. For example, the MEMS platform may be used for stable clock and frequency reference generation, and inertial sensing (e.g., acceleration and rotation rate).

In some embodiments, the MEMS platform may be created using a unique fabrication process that enables the following characteristics for a resonator, an accelerometer, or a gyroscope. For example, the MEMS platform may have high frequency bulk acoustic wave resonance modes with ultra-high quality factors (Q) and ultra-low motional impedances (Rm). In some examples, the MEMS platform may have multiple transduction ports with desirable geometrically defined coupling and without the need for metal electrodes and their patterning. In some examples, the MEMS platform may have a compensated temperature characteristic with second-order temperature behavior and a high turn-over temperature, an inherent immunity to shock and packaging stress, a wafer-level encapsulation with low-pressure, and fabrication and co-integration of resonators and sensors in a single fabrication and package process.

In some embodiments, a microfabrication process may be utilized to make a platform where one or more thin piezoelectric films with desirable polarization across the lateral and thickness directions are sandwiched between single-crystal silicon layers. The process may enable simultaneous excitation of high-Q and low Rₘ symmetric modes and non-symmetric acoustic resonance modes, as well as multi-port transducers for creation of mode-matched Coriolis gyroscopes and accelerometers with suppressed cross-axis sensitivity. Further, the process may also enable wafer-level packaging of the device at a desired pressure. In some examples, the process may be scaled by repeatedly forming a piezoelectric layer sandwiched between two silicon layers.

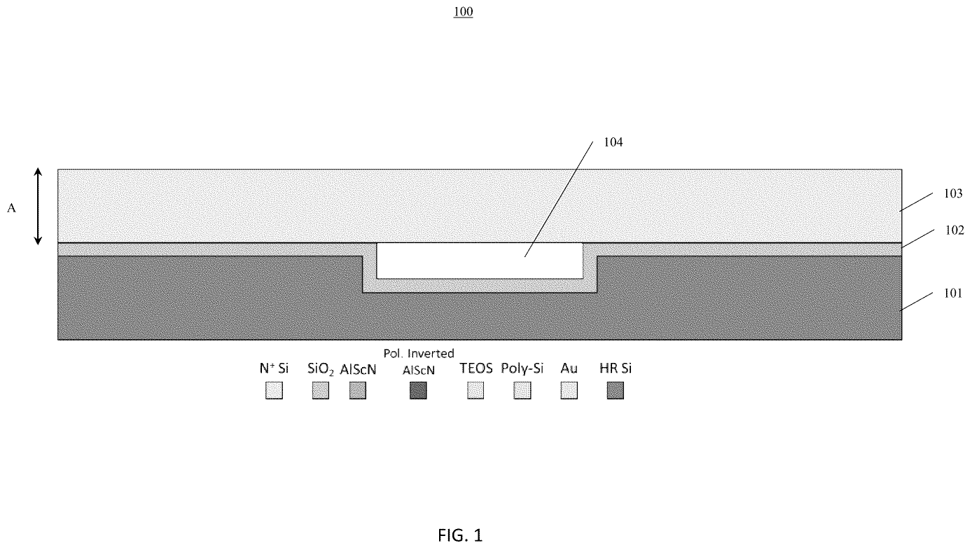

FIGS. 1-17 illustrate a schematic cross-sectional view at each step of the example manufacturing process flow for manufacturing the MEMS platform, according to some embodiments of the present disclosure.

FIG. 1 illustrates a schematic cross-sectional view of a cavity-embedded silicon-on-insulator (SOI) substrate, according to some embodiments of the present disclosure.

As shown in FIG. 1, the cavity-embedded SOI substrate 100 may include a handle layer 101 with a cavity 104. For example, the handle layer 101 may be a silicon layer with a high resistivity. In some examples, the cavity-embedded silicon-on-insulator substrate 100 may further include a SiO₂ layer 102 formed on the handle layer 101 and covering an inside surface of the cavity 104.

In some examples, the cavity-embedded SOI substrate 100 may further include a first device layer 103 formed on the SiO₂ layer 102 and covering the cavity 104. For example, the first device layer 103 may be an N-type doped (by Phosphorous or Antimony) silicon layer. For example, a thickness of the first device layer 103 may be a first thickness A.

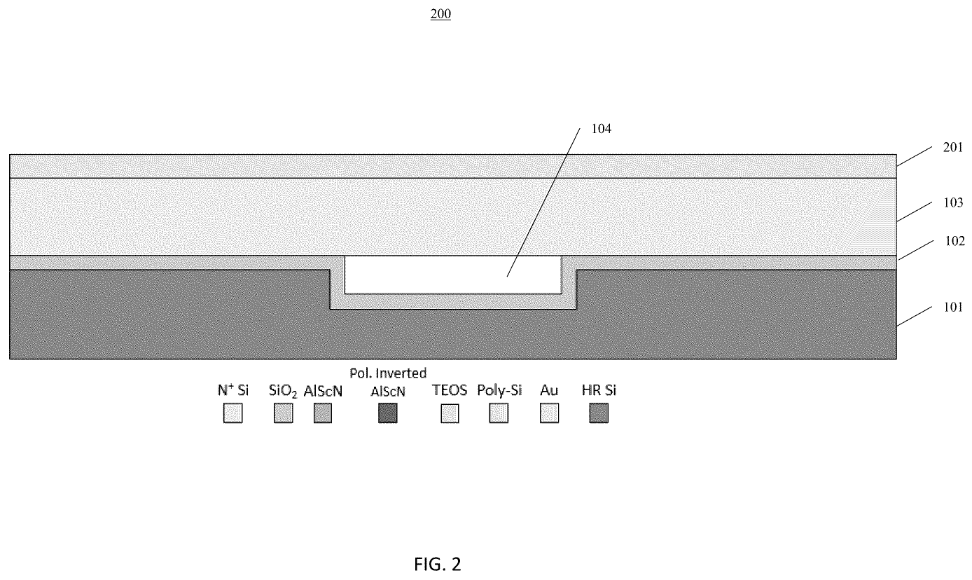

FIG. 2 illustrates a schematic cross-sectional view of a first tetraethyl orthosilicate (TEOS) layer formed on the first device layer, according to some embodiments of the present disclosure.

As shown in FIG. 2, the first TEOS layer 201 may be deposited on the first device layer 103. For example, the first TEOS layer 201 may have a thickness of 2 μm.

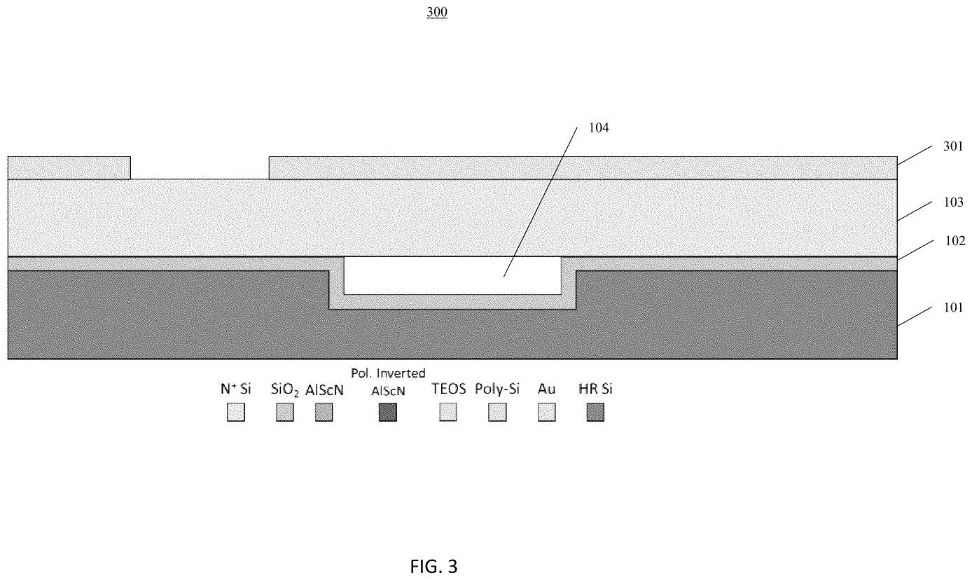

FIG. 3 illustrates a schematic cross-sectional view of a first patterned TEOS layer formed on the first device layer, according to some embodiments of the present disclosure.

As shown in FIG. 3, the first TEOS layer 201 may be patterned to form the first patterned TEOS layer 301. In some examples, the first patterned TEOS layer 301 may be formed by patterning the first TEOS layer 201 with a buffered oxide etching (BOE) process. For example, the first patterned TEOS layer 301 may be used as a mask for etching the first device layer 103.

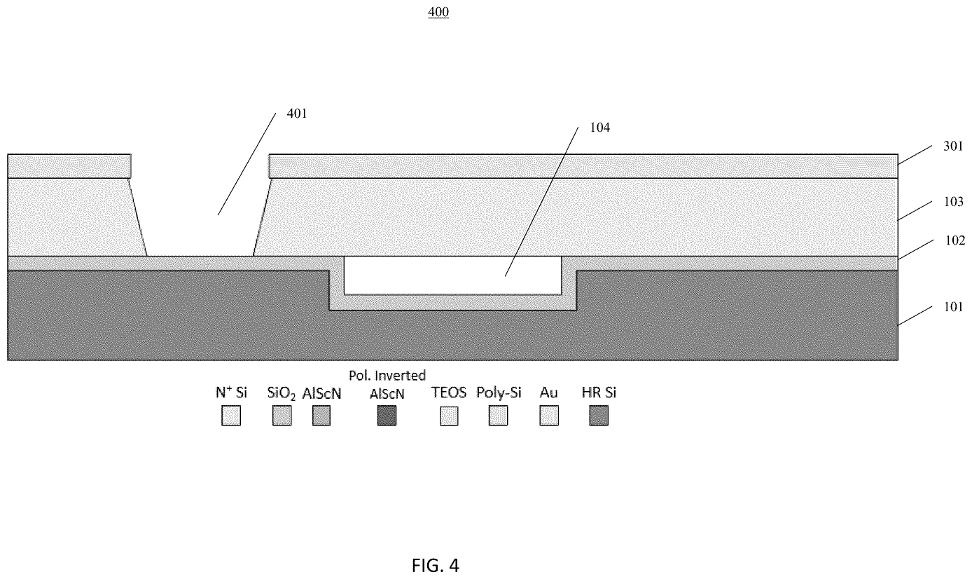

FIG. 4 illustrates a schematic cross-sectional view of a first trench formed in the first device layer, according to some embodiments of the present disclosure.

As shown in FIG. 4, a first trench 401 may be formed in the first device layer 103 be etching by using the first patterned TEOS layer 301 as a mask. For example, the first device layer 103 may be etched with a tetramethylammonium hydroxide (TMAH) solution. In some examples, the etching process may be stopped on (111) walls of the first device layer 103.

In some embodiments, the first patterned TEOS layer 301 may be removed after the first trench 401 is formed.

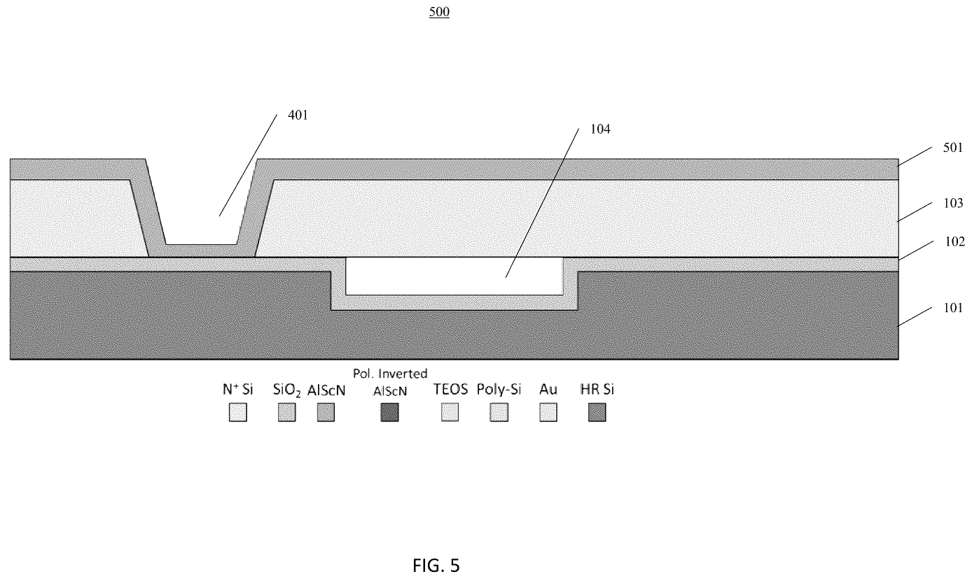

A piezoelectric layer may be deposited on the doped silicon layer. In some examples, the piezoelectric layer may be an aluminum-scandium-nitride (AlScN) piezoelectric layer (e.g., 501 as shown in FIG. 5).

FIG. 5 illustrates a schematic cross-sectional view of the aluminum-scandium-nitride (AlScN) piezoelectric layer formed on the first device layer, according to some embodiments of the present disclosure.

As shown in FIG. 5, the AlScN piezoelectric layer 501 may be grown on the first device layer 103 and on bottom and sidewalls of the first trench 401. For example, a thickness of the AlScN piezoelectric layer 501 may be 100 nm.

A polarization of the piezoelectric layer may be engineered.

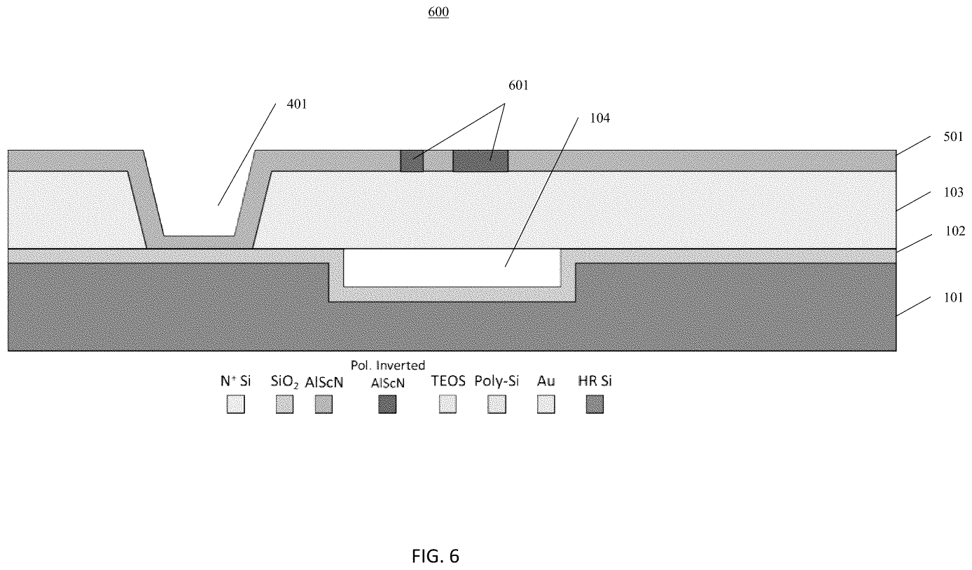

FIG. 6 illustrates a schematic cross-sectional view of an engineered AlScN piezoelectric layer formed on the first device layer, according to some embodiments of the present disclosure.

As shown in FIG. 6, the polarization of AlScN piezoelectric layer 501 is engineered according to a desirable pattern. For example, the engineered AlScN piezoelectric layer 601 may be formed in the AlScN piezoelectric layer 501. In some examples, the engineered AlScN piezoelectric layer 601 may be formed by pre-patterning a seed layer (e.g., aluminum) prior to the growth of the AlScN piezoelectric layer 501. In some examples, the engineered AlScN piezoelectric layer 601 may be formed by deposition and patterning of dummy electrodes in regions where the polarization is switched, followed by application of a polarization electric field, and a removal of the dummy electrodes using a dry etching process.

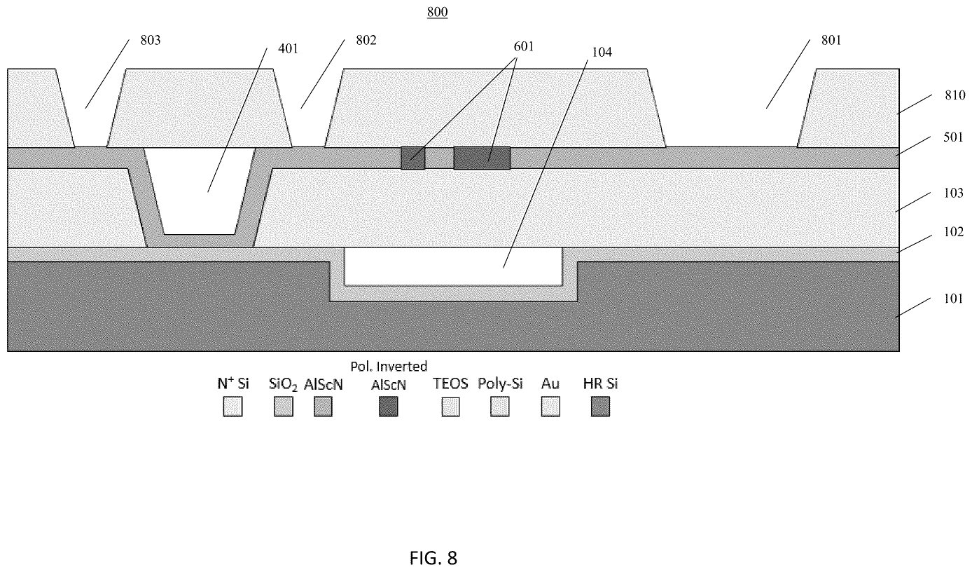

A second patterned silicon layer (e.g., 810 as shown in FIG. 8) is bonded on the piezoelectric layer.

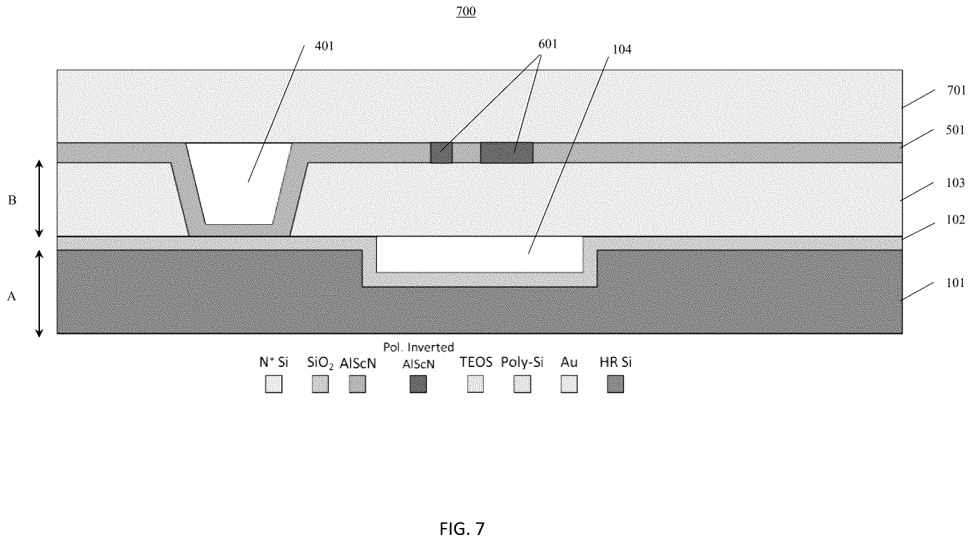

FIG. 7 illustrates a schematic cross-sectional view of a second device layer formed on the AlScN piezoelectric layer, according to some embodiments of the present disclosure.

As shown in FIG. 7, the second device layer 701 may be bonded to the AlScN piezoelectric layer 501. For example, the AlScN piezoelectric layer 501 may be sandwiched between the first device layer 103 and the second device layer 701. In some examples, the second device layer 701 may be an N-type doped (by Phosphorous or Antimony) silicon layer. In some examples, a thickness of the second device layer 701 may be a second thickness B.

In some embodiments, the first thickness A and the second thickness B may be the same. In some embodiments, the first thickness A and the second thickness B may be different. In some examples, the first thickness A and the second thickness B may be controlled to improve the performance of the MEMS platform.

FIG. 8 illustrates a schematic cross-sectional view of second trenches formed in the second device layer, according to some embodiments of the present disclosure.

As shown in FIG. 8, the second trenches (e.g., 801, 802, and 803) may be formed in the second device layer 701. For example, the second trenches (e.g., 801, 802, and 803) may be formed by dry etching the second device layer 701 to form the second patterned silicon layer.

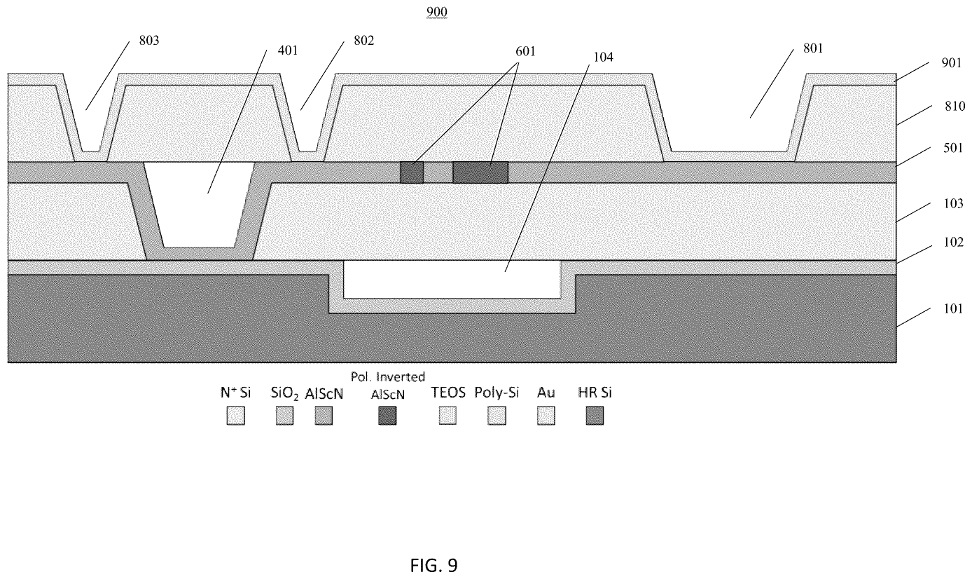

FIG. 9 illustrates a schematic cross-sectional view of a second TEOS layer formed on the second device layer, according to some embodiments of the present disclosure.

As shown in FIG. 9, the second TEOS layer 901 may be deposited on the second device layer 701. In some examples, the second TEOS layer 901 may cover a bottom and sidewalls of each of the second trenches (e.g., 801, 802, and 803). For example, the second TEOS layer 901 may have a thickness of 2 μm.

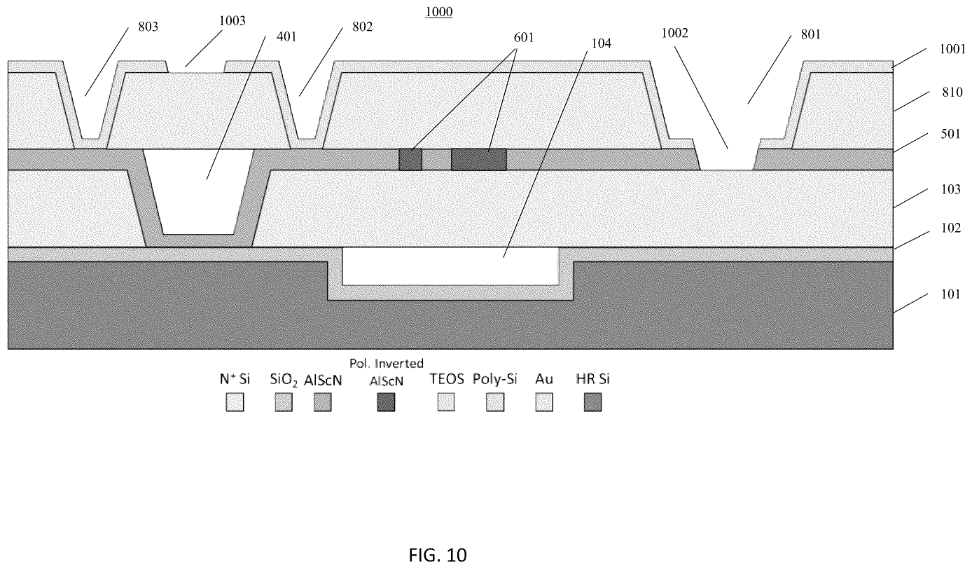

FIG. 10 illustrates a schematic cross-sectional view of a second patterned TEOS layer formed on the second device layer, according to some embodiments of the present disclosure.

As shown in FIG. 10, the second TEOS layer 901 may be patterned to form the second patterned TEOS layer 1001. In some examples, the second patterned TEOS layer 1001 may be formed by patterning the second TEOS layer 901 with a dry etching process.

In some embodiments, the AlScN piezoelectric layer 501 may be patterned in selected regions (e.g., 1002). For example, the AlScN piezoelectric layer 501 may be patterned by a dry etching process. For example, the AlScN piezoelectric layer 501 may be patterned to expose the first device layer 103.

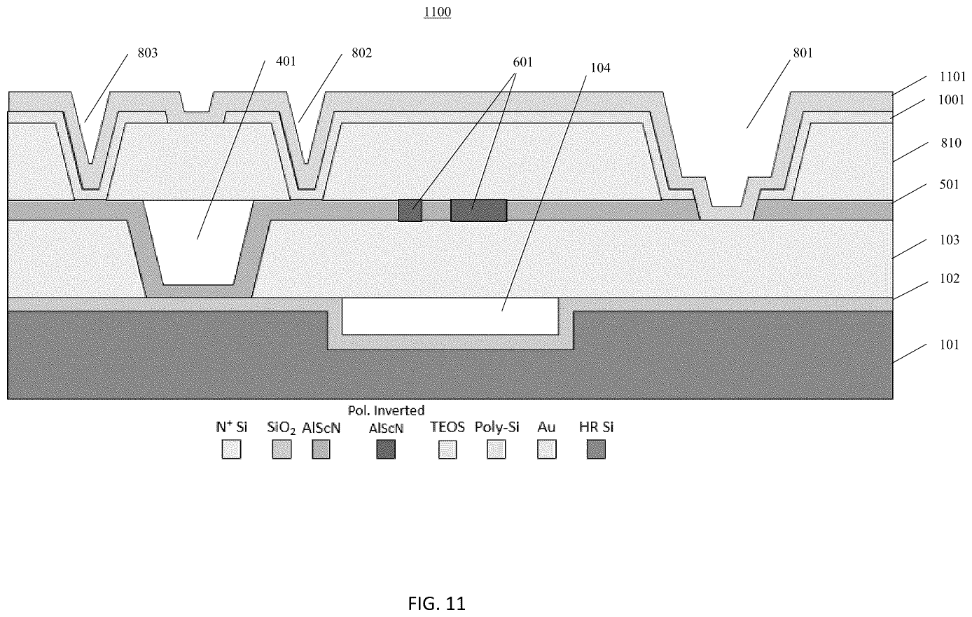

FIG. 11 illustrates a schematic cross-sectional view of a doped poly-silicon layer formed on the second patterned TEOS layer, according to some embodiments of the present disclosure.

As shown in FIG. 11, the doped poly-silicon layer 1101 may be conformally formed on the second patterned TEOS layer 1001 and an exposed surface of the first device layer 103. In some examples, the doped poly-silicon layer 1101 may be formed on the second patterned TEOS layer 1001 by deposition.

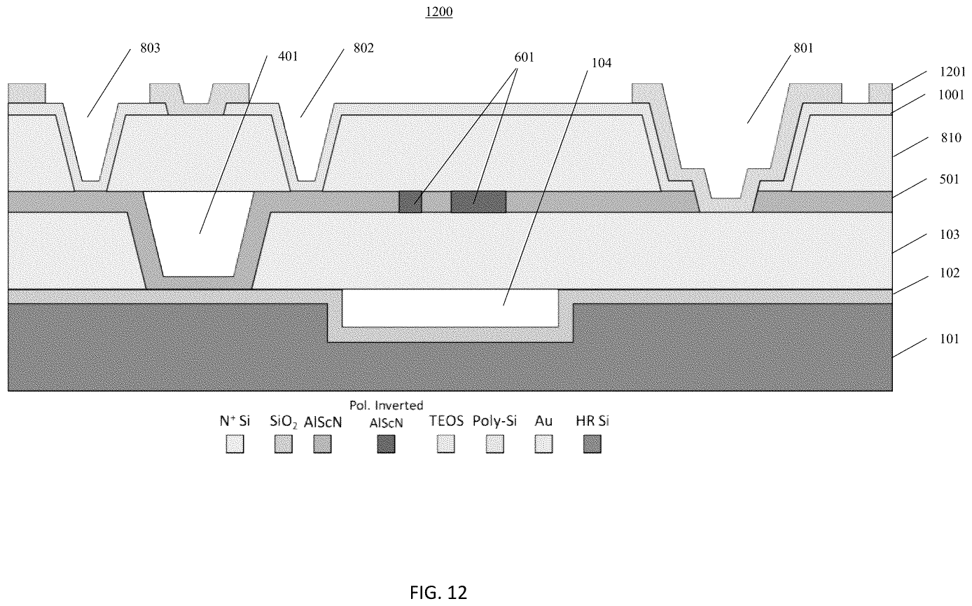

FIG. 12 illustrates a schematic cross-sectional view of a structure 1300 including a patterned doped poly-silicon layer formed on the second patterned TEOS layer, according to some embodiments of the present disclosure.

As shown in FIG. 12, the doped poly-silicon layer 1101 may be patterned to form the patterned doped poly-silicon layer 1201. In some examples, the doped poly-silicon layer 1101 may be formed by etching the second TEOS layer 901.

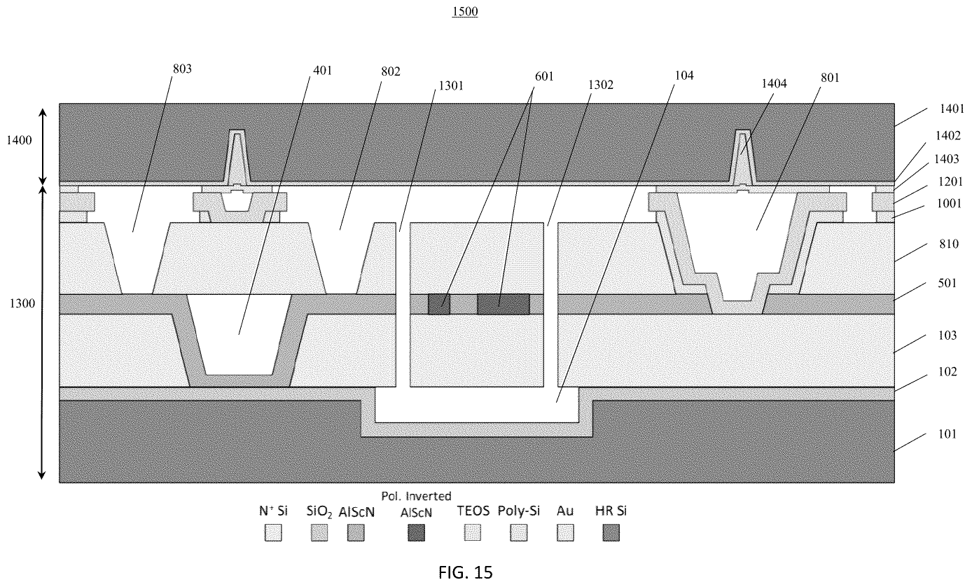

Third trenches (e.g., 1501 and 1502 as shown in FIG. 15) are formed through the second patterned silicon layer, the piezoelectric layer, and the first patterned silicon layer to define a resonator lateral geometry.

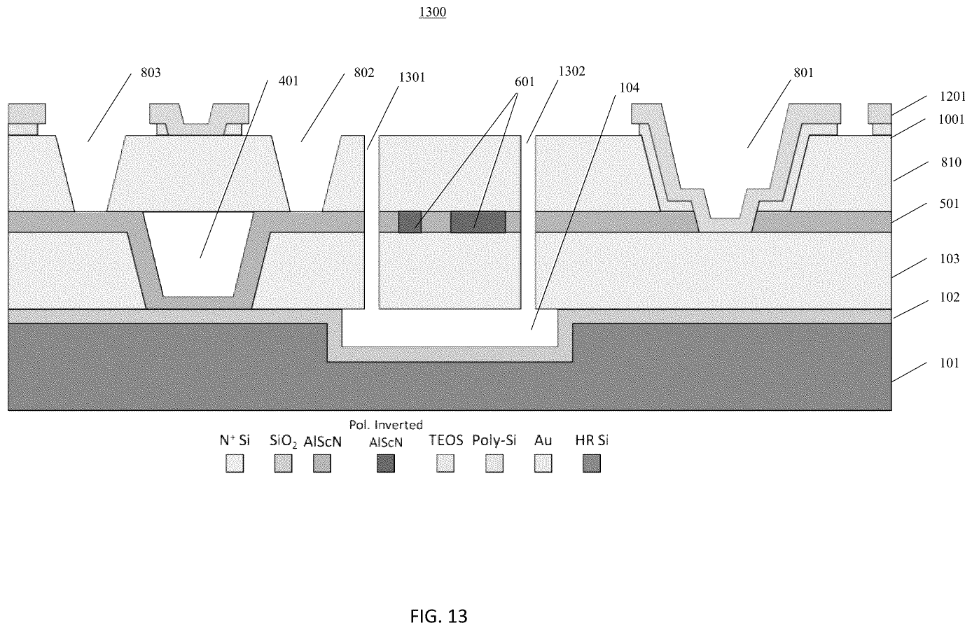

FIG. 13 illustrates a schematic cross-sectional view of the third trenches formed in the first device layer (e.g., the first patterned silicon layer), the piezoelectric layer (e.g., the AlScN piezoelectric layer), and the second device layer (e.g., the second patterned silicon layer), according to some embodiments of the present disclosure.

As shown in FIG. 13, the third trenches (e.g., 1301 and 1302) may be formed in in the first device layer 103, the AlScN piezoelectric layer 501, and the second device layer 701. For example, the third trenches (e.g., 1301 and 1302) may be formed by etching across the first device layer 103, the AlScN piezoelectric layer 501, and the second device layer 701. In some examples, resonator lateral geometry may be defined by the third trenches (e.g., 1301 and 1302).

In some embodiments, portions of the second patterned TEOS layer 1001 exposed by the patterned doped poly-silicon layer 1201 may be removed after the third trenches (e.g., 1301 and 1302) are formed.

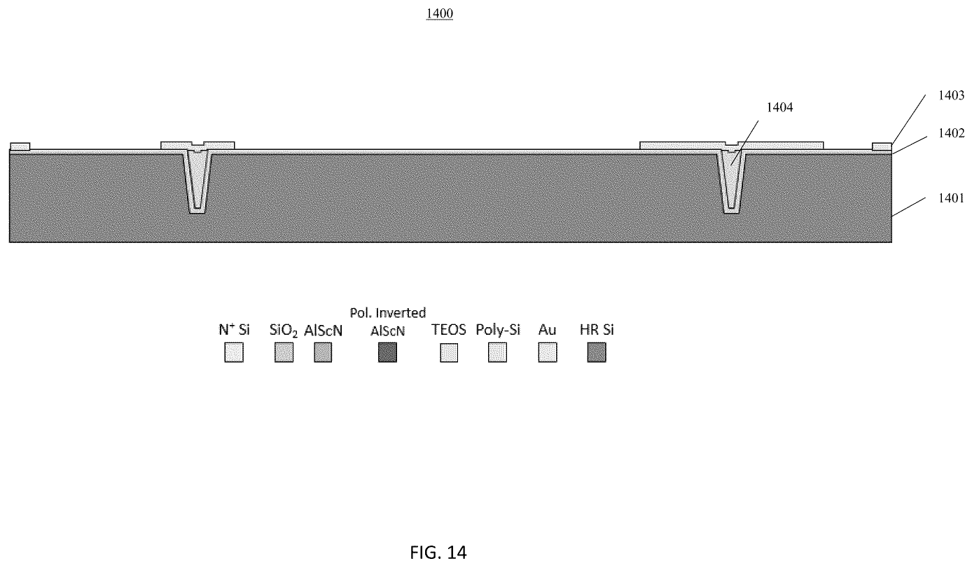

FIG. 14 illustrates a schematic cross-sectional view of a second substrate, according to some embodiments of the present disclosure.

As shown in FIG. 14, the second substrate 1400 may include a handle layer 1401 with trenches formed in the second substrate 1400. For example, the handle layer 1401 may have a high resistivity. In some examples, the trenches may be formed by a through-silicon-vias (TSVs) etching process.

In some examples, the second substrate 1400 may further include a SiO₂ layer 1402 conformally formed on the handle layer 1401 and covering inside surface of the trenches. For example, the SiO₂ layer 1402 may be formed by oxidating a surface of the handle layer 1401.

In some examples, the second substrate 1400 may further include poly-silicon pillars 1404 filling up the trenches of the handle layer 1401. In some examples, the poly-silicon pillars 1404 may be doped poly-silicon pillars.

In yet another example, the second substrate 1400 may further include a metal layer 1403 formed on the SiO₂ layer 102 and covering the poly-silicon pillars 1404. For example, the metal layer 1403 may be made of a material of Au. In some examples, the metal layer 1403 may be formed by an Au lift-off process.

FIG. 15 illustrates a schematic cross-sectional view of the second substrate bonded to the structure 1300, according to some embodiments of the present disclosure.

As shown in FIG. 15, the second substrate 1400 may be bonded to the structure 1300. For example, the second substrate 1400 may be bonded to the structure 1300 by bonding the metal layer 1403 of the second substrate 1400 to the patterned doped poly-silicon layer 1201 of the structure 1300. In some examples, the bonding may be performed at a desired pressure.

In some examples, the poly-silicon pillars 1404 may provide electrical contacts to the first device layer 103 and the second device layer 701.

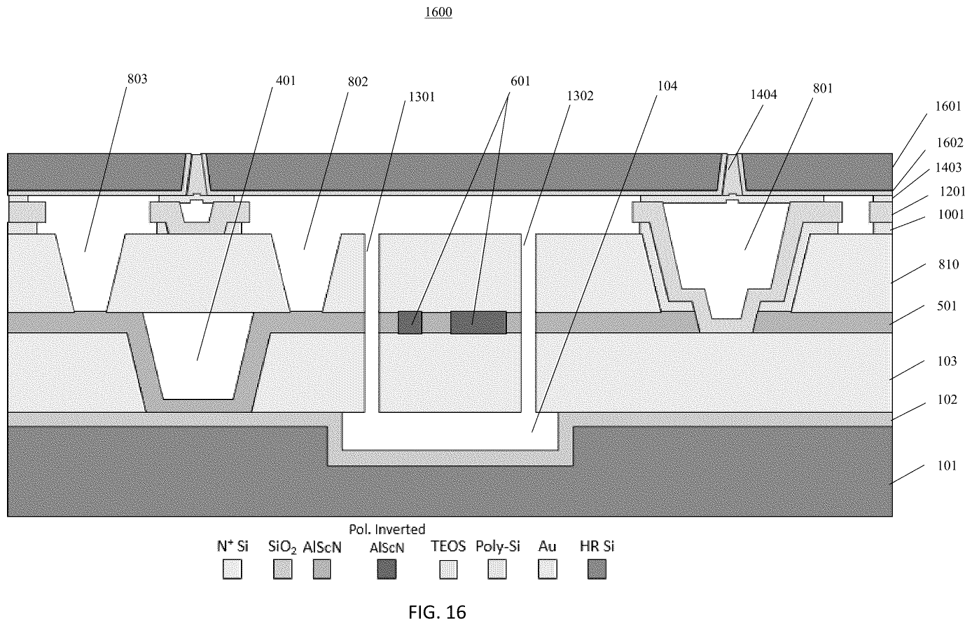

FIG. 16 illustrates a schematic cross-sectional view of a grinded second substrate bonded to the structure, according to some embodiments of the present disclosure.

As shown in FIG. 16, the second substrate 1400 may be grinded to expose the poly-silicon pillars 1404. For example, the handle layer 1401 may be grinded to form the grinded handle layer 1601 and the SiO₂ layer 1402 may be grinded to form the grinded SiO₂ layer 1602, such that the poly-silicon pillars 1404 is exposed.

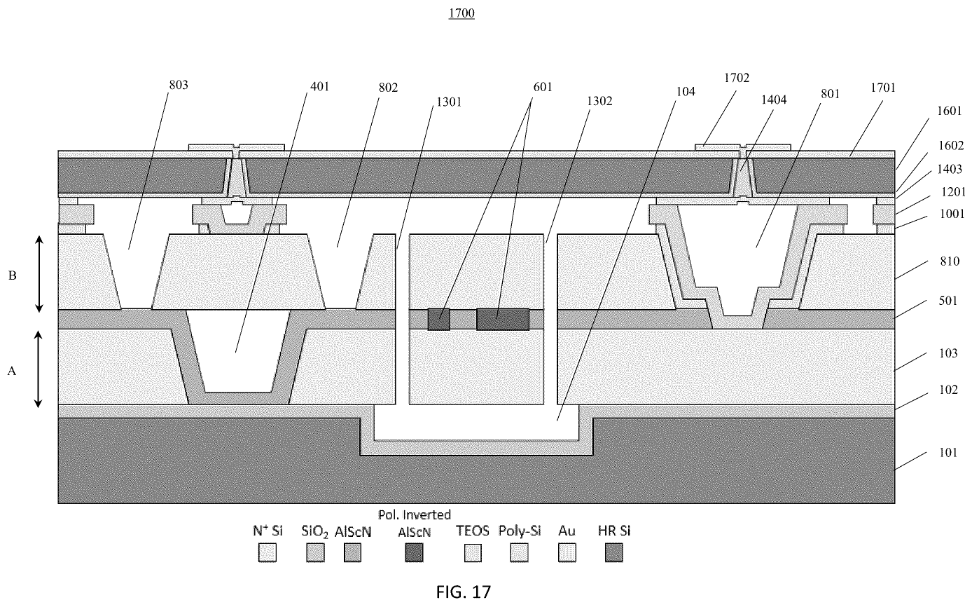

FIG. 17 illustrates a schematic cross-sectional view of contact pads formed on the grinded handle layer, according to some embodiments of the present disclosure.

As shown in FIG. 17, the contact pads 1702 may be formed on the grinded handle layer 1601. In some examples, the contact pads 1702 may provide electrical contacts to the poly-silicon pillars 1404.

Alternatively, in some examples, a third patterned TEOS layer 1701 may be formed on the grinded handle layer 1601 exposing the poly-silicon pillars 1404, and the contact pads 1702 may be formed on the third patterned TEOS layer 1701 to provide electrical contacts to the poly-silicon pillars 1404.

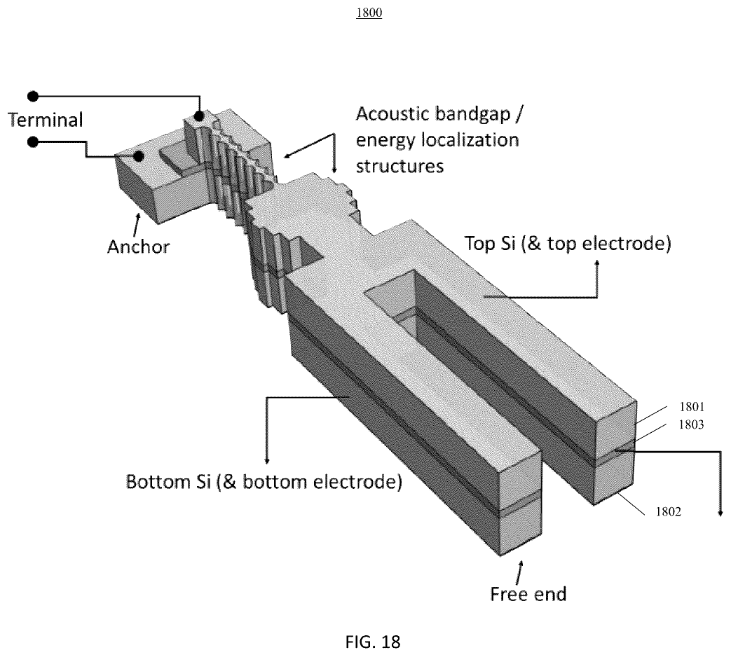

FIG. 18 illustrates a schematic perspective view of a resonator model, according to some embodiments of the present disclosure.

As shown in FIG. 18, the resonator model 1800 may operate in cross-sectional Lamé (X-Lamé) mode that provides high temperature stability with second-order characteristics. The lateral geometry may be designed to localize acoustic energy inside a cavity for high-Q operations. An electric field may be applied across a top silicon device layer 1801 and a bottom silicon device layer 1802, which enables electromechanical transduction of symmetric modes by a piezoelectric layer 1803.

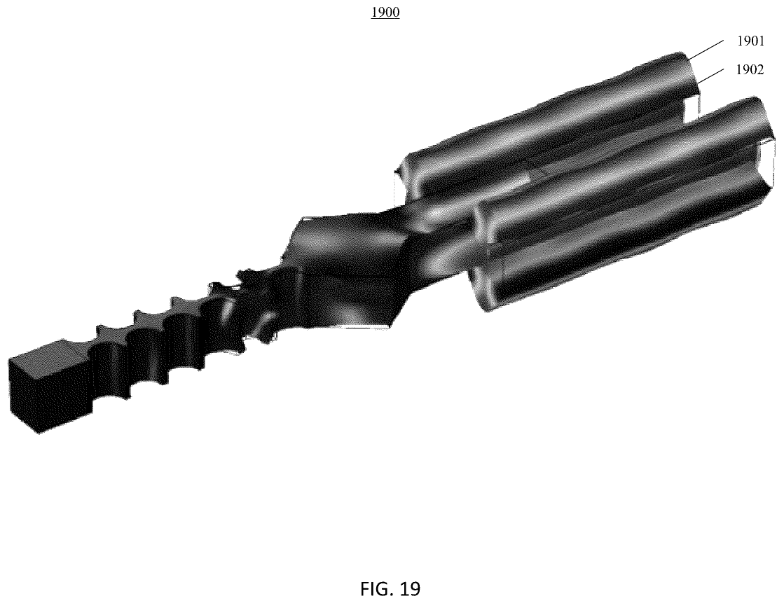

FIG. 19 illustrates a simulation of the resonator model, according to some embodiments of the present disclosure.

As shown in FIG. 19, the resonator model 1900 may have regions 1901 that are expanding and regions 1902 that are contracting.

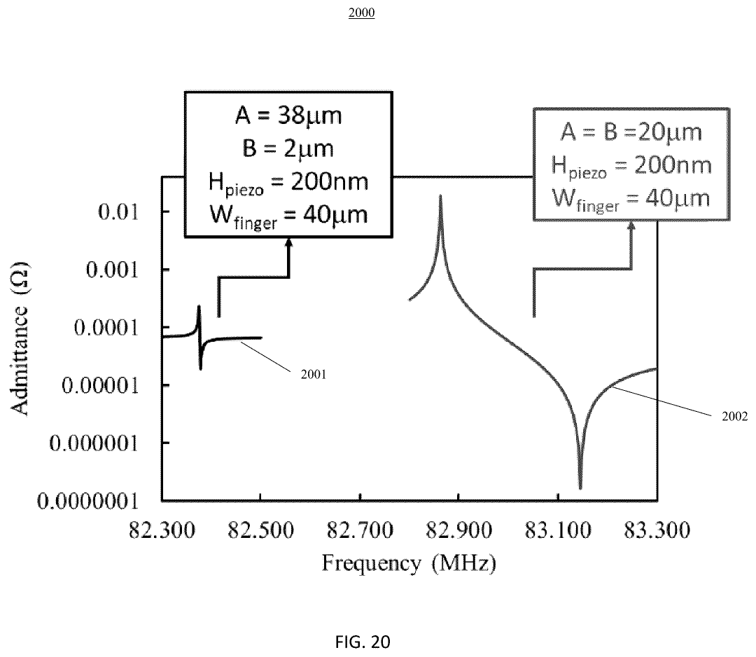

FIG. 20 illustrates a simulated admittance response as a function of a frequency of the resonator model in two scenarios, according to some embodiments of the present disclosure.

As shown in FIG. 20, a first admittance plot 2001 demonstrates a simulated admittance response as the function of the frequency of the resonator model when a thickness of the piezoelectric layer 1803 is 200 nm, a first thickness of the bottom silicon device layer 1802 is 2 μm, and a second thickness of the top silicon device layer 1801 is 38 μm. In addition, a second admittance plot 2002 demonstrates a simulated admittance response as the function of the frequency of the resonator model when the thickness of the piezoelectric layer 1803 is 200 nm, the first thickness of the bottom silicon device layer 1802 is 20 μm, and the second thickness of the top silicon device layer 1801 is 38 μm.

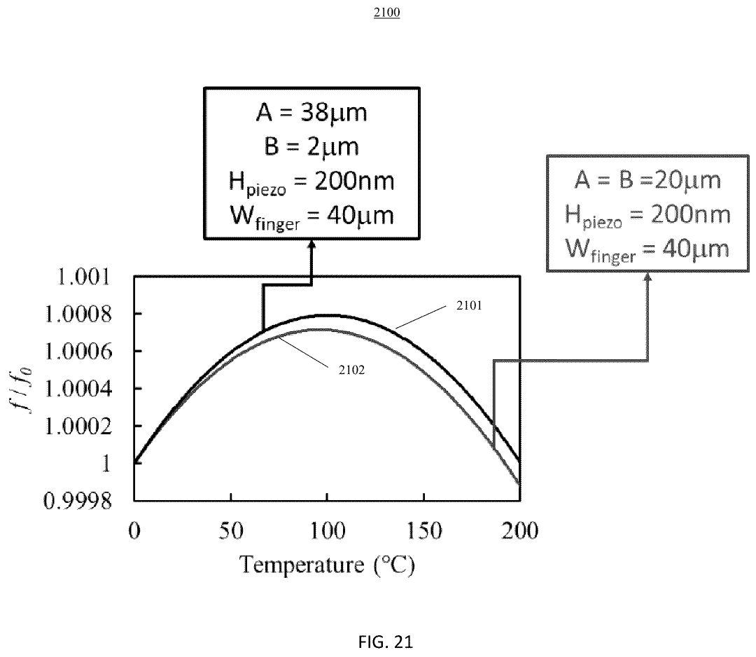

FIG. 21 illustrates a simulated temperature response as a function of a frequency of the resonator model in two scenarios, according to some embodiments of the present disclosure.

As shown in FIG. 21, a first temperature plot 2101 demonstrates a simulated temperature response as the function of the frequency of the resonator model when a thickness of the piezoelectric layer 1803 is 200 nm, a first thickness of the bottom silicon device layer 1802 is 2 μm, and a second thickness of the top silicon device layer 1801 is 38 μm. In addition, a second temperature plot 2102 demonstrates a simulated temperature response as the function of the frequency of the resonator model when the thickness of the piezoelectric layer 1803 is 200 nm, the first thickness of the bottom silicon device layer 1802 is 20 μm, and the second thickness of the top silicon device layer 1801 is 38 μm. Furthermore, the first temperature plot 2101 and the second temperature plot 2102 are simulated when both the top silicon device layer and the bottom silicon device layer are N-type doped with a resistivity of 0.0015 ohm·cm.

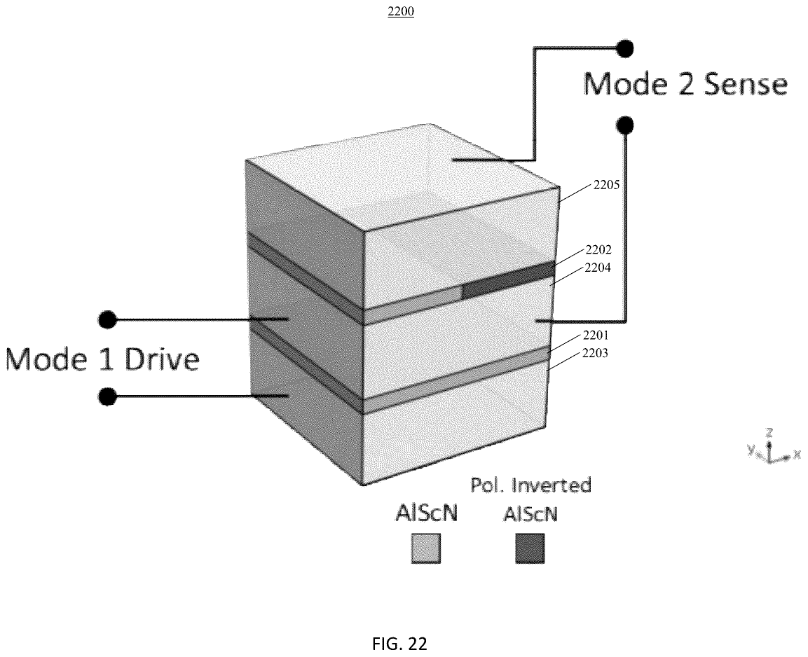

FIG. 22 illustrates a schematic perspective view of a gyroscope model, according to some embodiments of the present disclosure.

As shown in FIG. 22, the gyroscope model 2200 may be a mode-matched Coriolis gyroscope for pitch and roll, and yaw rotation rate detection. In some embodiments, the gyroscope model 2200 may include two piezoelectric layers (e.g., 2201 and 2202), each of which is sandwiched between two single-crystal silicon layers (e.g., 2203, 2204, and 2205). For example, the first piezoelectric layer 2201 may be sandwiched between a first single-crystal silicon layer 2203 and a second single-crystal silicon layer 2204, and the second piezoelectric layer 2202 may be sandwiched between a second single-crystal silicon layer 2204 and a third single-crystal silicon layer 2205.

The first piezoelectric layer 2201 is not treated for any polarization inversion while half of the second piezoelectric layer 2202 is subjected to the polarization switching. A drive mode (Mode 1) may be excited with application of an electric field between the first single-crystal silicon layer 2203 and the second single-crystal silicon layer 2204. The drive mode (Mode 1) will not be detected by the second piezoelectric layer 2202, considering charge cancellation resulted from the partially inverted polarization.

In some embodiments, upon ZX rotation, energy of the drive mode (mode 1) may be transferred to energy of the drive mode (mode 2), due to Coriolis principle. An efficiency of the transfer depends on a match between the frequency of mode 1 and mode 2. For example, a perfect match can be achieved by proper definition of the thickness of the piezoelectric layers (e.g., 2201 and 2202), the thickness of the single-crystal silicon layers (e.g., 2202, 2204, and 2205), and lateral dimensions of the gyroscope model 2200. Considering the mode-shape of the mode 2 and partially inverted polarization of the second piezoelectric layer 2202, the mode 2 may be perfectly sensed by measuring electric charges excited between the second single-crystal silicon layer 2204 and a third single-crystal silicon layer 2205.

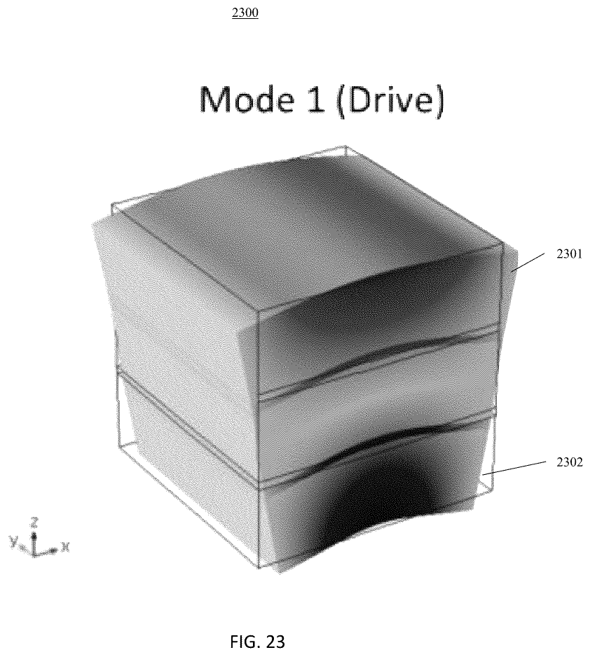

FIG. 23 illustrates a simulation of the gyroscope model in mode 1, according to some embodiments of the present disclosure.

As shown in FIG. 23, the gyroscope model 2300 may have regions 2301 that are expanding and regions 2302 that are contracting.

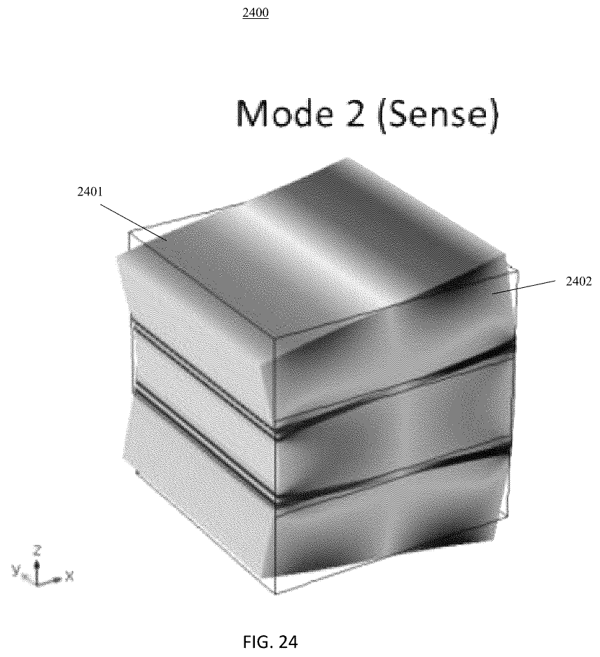

FIG. 24 illustrates a simulation of the gyroscope model in mode 2, according to some embodiments of the present disclosure.

As shown in FIG. 24, the gyroscope model 2400 may have regions 2401 that are expanding and regions 2402 that are contracting.

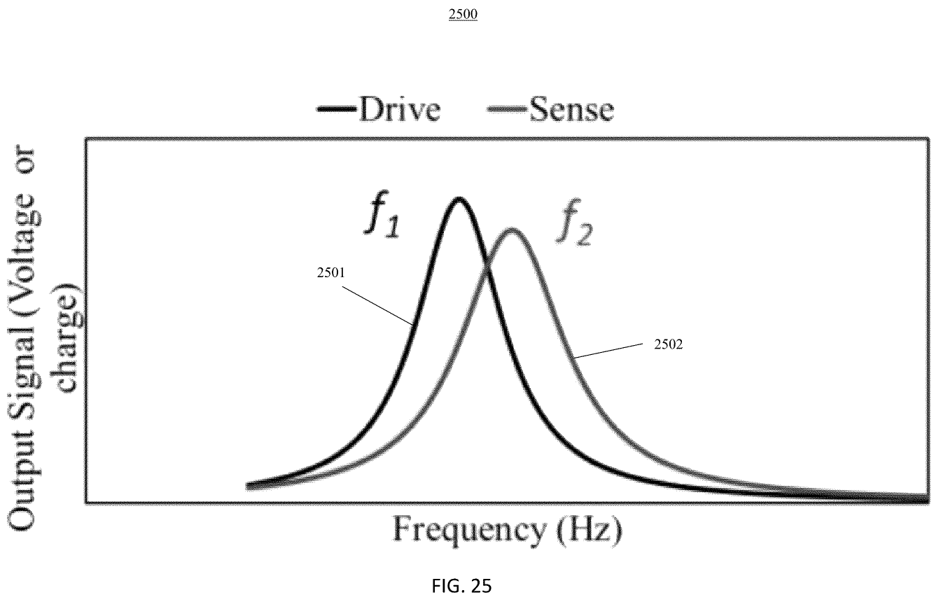

FIG. 25 illustrates a simulated output signal response as a function of a frequency of the gyroscope model, according to some embodiments of the present disclosure.

As shown in FIG. 25, a drive signal plot 2501 demonstrates a drive signal response as the function of the frequency of the gyroscope model, and a sense signal plot 2502 demonstrates a drive signal response as the function of the frequency of the gyroscope model.

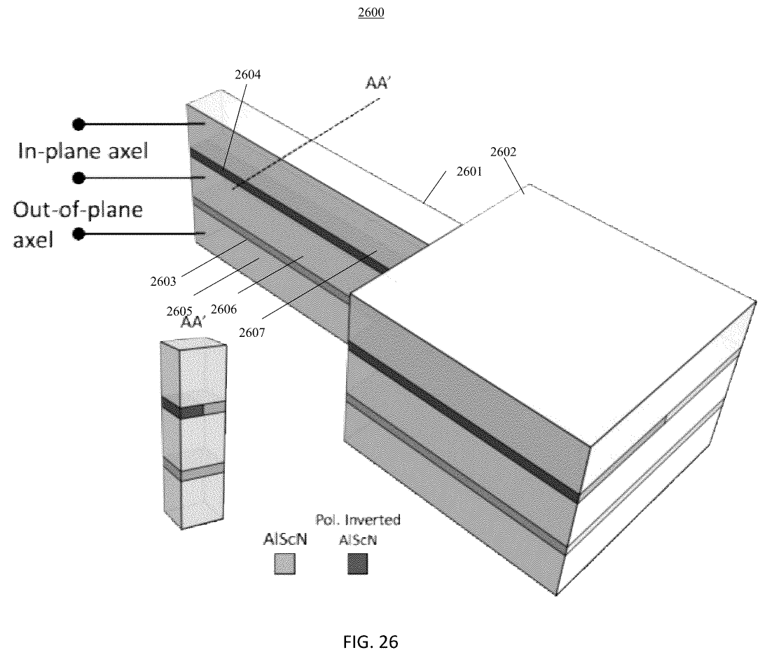

FIG. 26 illustrates a schematic perspective view of an accelerometer model, according to some embodiments of the present disclosure.

As shown in FIG. 26, the accelerometer model 2600 may be an in- and out-of-plane accelerometer (axels) without any cross-axis sensitivity. In some embodiments, the accelerometer model 2600 may include a beam 2601 and a proof-mass 2602 attached to the beam 2601. The accelerometer model 2600 may include two piezoelectric layers (e.g., 2603 and 2604), each of which is sandwiched between two single-crystal silicon layers (e.g., 2605, 2606, and 2607). For example, the first piezoelectric layer 2603 may be sandwiched between a first single-crystal silicon layer 2605 and a second single-crystal silicon layer 2606, and the second piezoelectric layer 2604 may be sandwiched between a second single-crystal silicon layer 2606 and a third single-crystal silicon layer 2607.

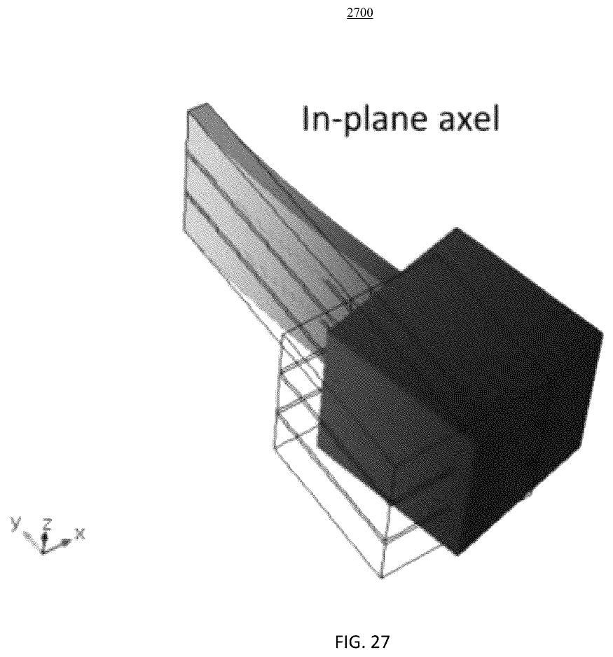

FIG. 27 illustrates a simulation of the accelerometer model with an in-plane axel, according to some embodiments of the present disclosure.

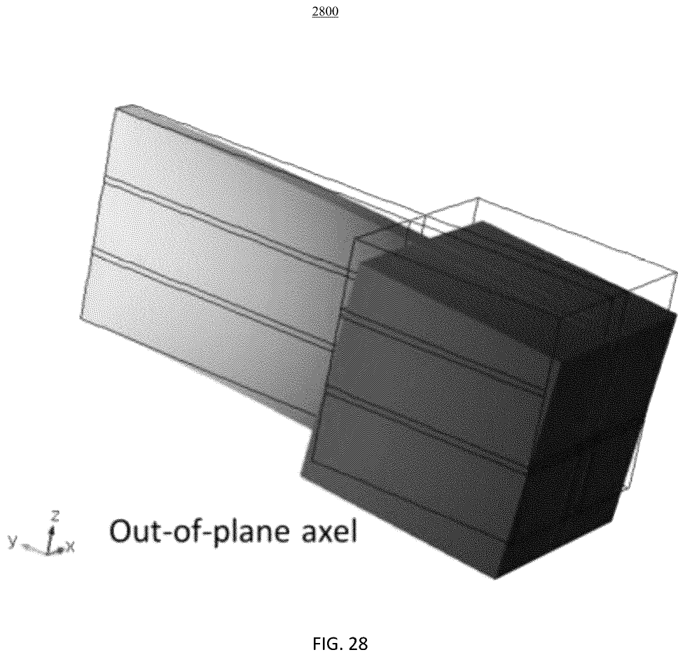

FIG. 28 illustrates a simulation of the accelerometer model with an out-of-plane axel, according to some embodiments of the present disclosure.

As shown in FIG. 27, in some embodiments, upon acceleration in an X direction (e.g., in-plane), the second piezoelectric layer 2604 excites charges, and no charge is excited through the first piezoelectric layer 2603 due to charge cancellation. However, as shown in FIG. 28, in some embodiments, upon acceleration in a Z direction (e.g., out-of-plane), the first piezoelectric layer 2603, which is not subjected to any partial polarization inversion, excites charges, and the second piezoelectric layer 2604 does not induce any charges. Therefore, a multi-axis accelerometer with cross-axis immunity is created.

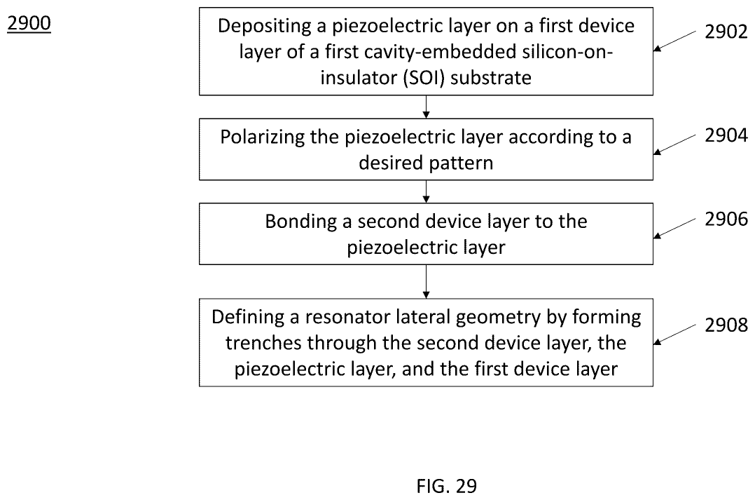

FIG. 29 depicts example operations 2900 for use with embodiments of the present disclosure. In some embodiments, a method 2900 for manufacturing a micro-electro-mechanical systems (MEMS) platform includes depositing 2902 a piezoelectric layer on a first device layer of a first cavity-embedded silicon-on-insulator (SOI) substrate. In some embodiments, the first device layer is N-type doped and comprises a first thickness.

The method 2900 may further include polarizing 2902 the piezoelectric layer according to a desired pattern.

The method 2900 may further include bonding 2904 a second device layer comprising a second thickness to the piezoelectric layer. In some embodiments, the second device layer is N-type doped.

The method 2900 may further include defining 2908 a resonator lateral geometry by forming trenches through the second device layer, the piezoelectric layer, and the first device layer.

In some embodiments, polarizing the piezoelectric layer includes depositing dummy electrodes in selected regions of the piezoelectric layer, applying an electric field to change a polarization of the selected regions of the piezoelectric layer, and removing the dummy electrodes.

In some embodiments, the first cavity-embedded silicon-on-insulator (SOI) substrate further comprises a handle layer.

In some embodiments, the handle layer comprises a cavity, and the first device layer is formed on the handle layer covering the cavity.

In some embodiments, the method 2900 includes, prior to depositing the piezoelectric layer on the first device layer depositing (not shown in FIG. 29) a first tetraethyl orthosilicate (TEOS) layer on the first device layer, and patterning the first TEOS layer (not shown in FIG. 29).

In some embodiments, the method 2900 includes patterning the second device layer, and depositing a second TEOS layer on the second device layer.

In some embodiments, the method 2900 includes, prior to forming the trenches, patterning the second TEOS layer, depositing a doped poly-silicon layer conformally on the second TEOS layer, and patterning the doped poly-silicon layer to form a patterned doped poly-silicon layer.

In some embodiments, the method includes, after forming the trenches, bonding a second substrate on the patterned doped poly-silicon layer. In some embodiments, the second substrate comprises embedded poly-silicon and gold metallization.

In some embodiments, the second substrate comprises poly-silicon pillars to provide electrical contact to the first device layer and the second device layer.

In some embodiments, the second substrate further comprises contact pads electrically connected to the poly-silicon pillars.

In some embodiments, the piezoelectric layer comprises an AlScN piezoelectric layer.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A method for manufacturing a micro-electro-mechanical systems (MEMS) platform, comprising:
depositing a piezoelectric layer on a first device layer of a first cavity-embedded silicon-on-insulator (SOI) substrate, wherein the first device layer is N-type doped and comprises a first thickness;
polarizing the piezoelectric layer according to a desired pattern;
bonding a second device layer comprising a second thickness to the piezoelectric layer, wherein the second device layer is N-type doped; and
defining a resonator lateral geometry by forming trenches through the second device layer, the piezoelectric layer, and the first device layer.

2. The method of claim 1, wherein polarizing the piezoelectric layer comprises:
depositing dummy electrodes in selected regions of the piezoelectric layer;
applying an electric field to change a polarization of the selected regions of the piezoelectric layer; and
removing the dummy electrodes.

3. The method of claim 1, wherein the first cavity-embedded silicon-on-insulator (SOI) substrate further comprises a handle layer.

4. The method of claim 3, wherein the handle layer comprises a cavity, and the first device layer is formed on the handle layer covering the cavity.

5. The method of claim 1, further comprising, prior to depositing the piezoelectric layer on the first device layer:
depositing a first tetraethyl orthosilicate (TEOS) layer on the first device layer; and
patterning the first TEOS layer.

6. The method of claim 5, further comprising:
patterning the second device layer; and
depositing a second TEOS layer on the second device layer.

7. The method of claim 6, further comprising, prior to forming the trenches:
patterning the second TEOS layer;
depositing a doped poly-silicon layer conformally on the second TEOS layer; and
patterning the doped poly-silicon layer to form a patterned doped poly-silicon layer.

8. The method of claim 7, further comprising, after forming the trenches:
bonding a second substrate on the patterned doped poly-silicon layer, wherein the second substrate comprises embedded poly-silicon and gold metallization.

9. The method of claim 8, wherein the second substrate comprises poly-silicon pillars to provide electrical contact to the first device layer and the second device layer.

10. The method of claim 9, wherein the second substrate further comprises contact pads electrically connected to the poly-silicon pillars.

11. The method of claim 1, wherein the piezoelectric layer comprises an AlScN piezoelectric layer.

12. A micro-electro-mechanical systems (MEMS) platform, comprising:
a first cavity-embedded silicon-on-insulator (SOI) substrate comprising a first device layer that is N-type doped and having a first thickness;
a piezoelectric layer deposited on the first device layer, wherein the piezoelectric layer is polarized according to a pattern;
a second device layer bonded to the piezoelectric layer, wherein the second device layer is N-type doped and has a second thickness; and
trenches formed through the second device layer, the piezoelectric layer, and the first device layer, wherein the trenches define a resonator lateral geometry.

13. The MEMS platform of claim 12, wherein the first cavity-embedded silicon-on-insulator (SOI) substrate further comprises a handle layer.

14. The MEMS platform of claim 13, wherein the handle layer comprises a cavity, and wherein the first device layer is formed on the handle layer covering the cavity.

15. The MEMS platform of claim 12, wherein the piezoelectric layer comprises an AlScN piezoelectric layer.

16. The MEMS platform of claim 12, further comprising a first tetraethyl orthosilicate (TEOS) layer deposited on the first device layer, wherein the first TEOS layer is patterned.

17. The MEMS platform of claim 16, further comprising a second TEOS layer deposited on the second device layer, wherein the second device layer is patterned and wherein the second TEOS layer is patterned.

18. The MEMS platform of claim 17, further comprising a doped poly-silicon layer conformally deposited on the second TEOS layer, wherein the doped poly-silicon layer is patterned.

19. The MEMS platform of claim 18, further comprising, a second substrate bonded on the doped poly-silicon layer, wherein the second substrate comprises embedded poly-silicon and gold metallization, and wherein the second substrate comprises poly-silicon pillars to provide electrical contact to the first device layer and the second device layer.

20. The MEMS platform of claim 19, wherein the second substrate further comprises contact pads electrically connected to the poly-silicon pillars.
